(19) United States
(12) Patent Application Publication
(10) Pub. No.: US 2015/0221592 A1
(43) Pub. Date: Aug. 6, 2015

(54) SEMICONDUCTOR DEVICE WITH PACKAGE-LEVEL DECOUPLING CAPACITORS FORMED WITH BOND WIRES

(71) Applicants: Chetan Verma, Noida (IN); Rishi Bhooshan, Ghaziabad (IN); Vikas Garg, Vasundhra Enclave (IN); Shailesh Kumar, Ghaziabad (IN); Navas Khan Oratti Kalandar, Petaling Jaya (MY)

(72) Inventors: Chetan Verma, Noida (IN); Rishi Bhooshan, Ghaziabad (IN); Vikas Garg, Vasundhra Enclave (IN); Shailesh Kumar, Ghaziabad (IN); Navas Khan Oratti Kalandar, Petaling Jaya (MY)

(21) Appl. No.: 14/170,651

(22) Filed: Feb. 3, 2014

(51) Int. Cl. H01L 23/522; H01L 23/00

(52) U.S. Cl. CPC H01L 23/5222; H01L 24/49; H01L 23/5221; H01L 2224/04042; H01L 2224/4903; H01L 2224/4813; H01L 2224/48157; H01L 2924/1205; H01L 2924/14; H01L 2224/48101; H01L 2224/49175; H01L 2224/48091

(57) ABSTRACT

A decoupling capacitor (decap) for circuitry (e.g., an I/O interface) in a semiconductor die is formed using one or more pairs of (parallel) bond wires wire-bonded to bond pads on a top surface of the die. Depending on the implementation, the pairs of bond wires may be horizontally or vertically aligned and may be bonded to I/O and/or array bond pads.

### BACKGROUND OF THE INVENTION

The present invention relates generally to packaged semiconductor devices, and more particularly to techniques for implementing decoupling capacitors for integrated circuitry in packaged semiconductor devices.

A packaged semiconductor device typically includes one or more integrated circuit (IC) dies mounted on a lead frame or substrate within a package housing. Each die is wire-bonded to leads and/or to other dies, and the sub-assembly is encapsulated within a suitable molding compound.

In some packaged semiconductor devices, a die has integrated circuitry, such as a high-speed double data rate (DDR) input/output (I/O) interface, that requires a local decoupling capacitor (a.k.a. a decap) to provide charge for proper operation of the interface (e.g., for maintaining power and signal integrity). Conventionally, the decap is implemented at the board level, the package level, or the die level.

At the board level, the decap is a discrete capacitor that is mounted on the printed circuit board (PCB) near where the packaged semiconductor device is mounted. Although near the package device, the decap may be too far from the related integrated circuitry on the die to be optimally effective and is also relatively costly to implement.

At the package level, the decap is a discrete capacitor that is mounted on the die within the package housing. This too is a relatively costly solution.

At the die level, the decap is implemented in silicon on the die. This solution results in the undesirable use of limited die area.

### BRIEF DESCRIPTION OF THE DRAWINGS

The present invention is illustrated by way of example and is not limited by the accompanying figures, in which like references indicate similar elements. Elements in the figures are illustrated for simplicity and clarity and have not necessarily been drawn to scale. For example, the thicknesses of layers and regions may be exaggerated for clarity.

FIG. 1 illustrates a die of a packaged semiconductor device according to one embodiment of the present invention;

FIG. 2 shows a top view of two horizontally aligned bond wires of the die of FIG. 1;

FIG. 3 represents a die of a packaged semiconductor device according to another embodiment of the invention;

FIG. 4 shows a side view of two vertically stacked bond wires of the die of FIG. 3;

FIG. 5 represents three other ways of implementing decaps according to three other embodiments of the invention;

FIG. 6 represents a die of a packaged semiconductor device according to another embodiment of the invention; and

FIG. 7 represents another die decap for a packaged semiconductor device according to another embodiment of the invention.

### DETAILED DESCRIPTION OF THE INVENTION

Detailed illustrative embodiments of the present invention are disclosed herein. However, specific structural and functional details disclosed herein are merely representative for purposes of describing example embodiments of the present invention. The present invention may be embodied in many alternate forms and should not be construed as limited to only the embodiments set forth herein. Further, the terminology used herein is for the purpose of describing particular embodiments only and is not intended to be limiting of example embodiments of the invention.

As used herein, the singular forms “a,” “an,” and “the,” are intended to include the plural forms as well, unless the context clearly indicates otherwise. It further will be understood that the terms “comprises,” “comprising,” “includes,” and/or “including,” specify the presence of stated features, steps, or components, but do not preclude the presence or addition of one or more other features, steps, or components. It also should be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

In one embodiment, the present invention is a packaged semiconductor device comprising a die having a plurality of bond pads and at least first and second bond wires. The first bond wire is wire-bonded between a first bond pad and a second bond pad, wherein the first and second bond pads are configured to be charged to a first voltage level. The second bond wire is wire-bonded between a third bond pad and a fourth bond pad and adjacent to the first bond wire, wherein the third and fourth bond pads are configured to be charged to a second voltage level different from the first voltage level such that the first and second bond wires function as a decoupling capacitor for the die.

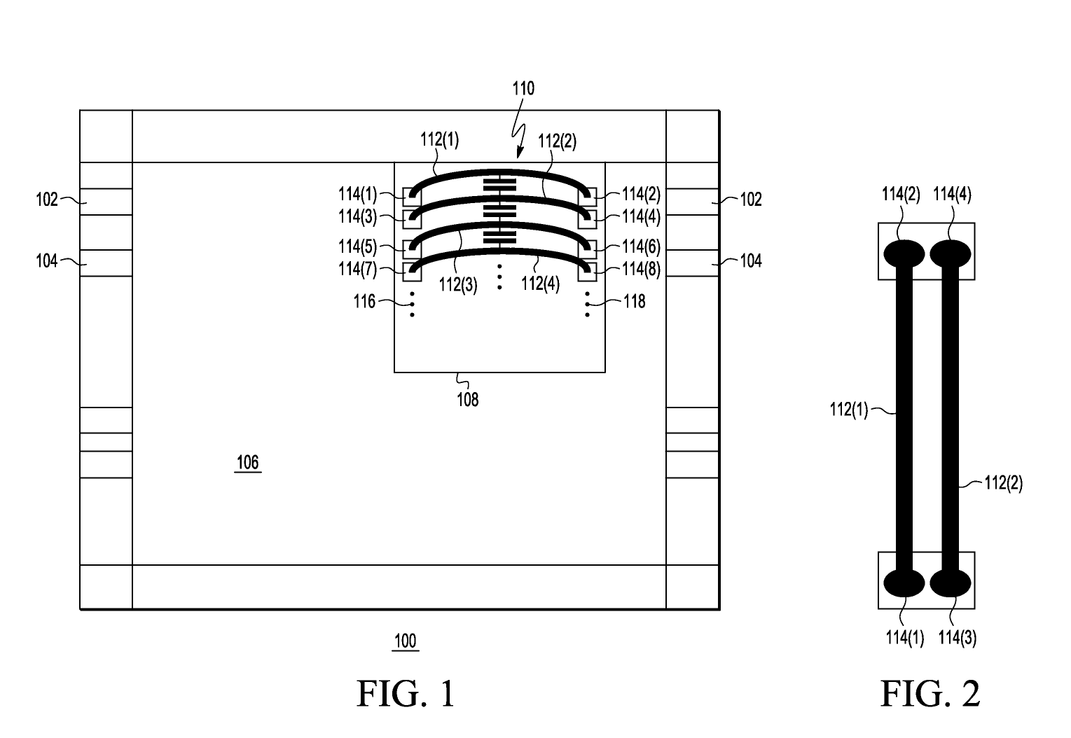

FIG. 1 represents a die 100 of a packaged semiconductor device according to one embodiment of the invention. As shown in FIG. 1, located around the periphery of die 100 are numerous I/O (i.e., peripheral) bond pads available to be wire-bonded off-chip with bond wires (not shown), including those designed to bring external power supply and ground voltages to the die through these pads. For example, bond pad 102 is a power pad designed to bring an external power supply voltage to the die, while bond pad 104 is a ground pad designed to bring an external ground voltage to the die. Note that die 100 may have a number of different power pads designed to bring the same or different power supply voltages to the die and/or a number of different ground pads designed to bring the same or different ground voltages to the die. Die 100 also has numerous I/O pads (not explicitly shown) designed to convey data signals to and from the chip via bond wires.

As known in the art, each power/ground pad has associated with it an underlying via structure (not shown) that conveys the power/ground voltage from the top (e.g., Alcap) die layer 106 to one or more lower metal die layers (not shown) having one or more metal traces (not shown) that convey the power/ground voltage to integrated circuitry (not shown) of the die that needs that power/ground voltage.

FIG. 1 also shows a rectangle 108 representing the location within die 100 of integrated circuitry, such as a high-speed DDR interface or any other circuitry that needs a dedicated decap. As described previously, for proper operation, this interface requires a decoupling capacitor or decap to be implemented preferably near the interface. According to this embodiment of the invention, decap 110 for interface 108 is implemented using a predetermined number of insulated wires. Only four such insulated bond wires 112(1)-112(4) wire-bonded to four corresponding pairs of array (i.e., interior) bond pads 114(1)-114(8) are shown in FIG. 1 for ease of understanding.

In particular:
Bond wire 112(1) is wire-bonded between array bond pads 114(1) and 114(2), where one or both of bond pads 114(1) and 114(2) are electrically connected by an underlying via structure (not shown) to a metal trace (not shown) carrying the power supply voltage for interface 108;
Bond wire 112(2) is wire-bonded between array bond pads 114(3) and 114(4), where one or both of bond pads 114(3) and 114(4) are electrically connected by an underlying via structure (not shown) to a metal trace (not shown) carrying the ground voltage for interface 108;
Bond wire 112(3) is wire-bonded between array bond pads 114(5) and 114(6), where one or both of bond pads 114(5) and 114(6) are electrically connected by an underlying via structure (not shown) to a metal trace (not shown) carrying the power supply voltage for interface 108;
Bond wire 112(4) is wire-bonded between array bond pads 114(7) and 114(8), where one or both of bond pads 114(7) and 114(8) are electrically connected by an underlying via structure (not shown) to a metal trace (not shown) carrying the ground voltage for interface 108.

As indicated above, for each bond wire 112, one or both of the corresponding array bond pads 114 are electrically connected by a corresponding underlying via structure to a metal trace carrying the appropriate voltage level. If both array bond pads are connected to respective metal traces carrying the same voltage level, then the bond wire will also be charged to that same voltage level and no current will flow through the bond wire.

On the other hand, if only one of the two array bond pads 114 for a particular bond wire 112, is connected to a metal trace charged to the appropriate voltage level, then the second array bond pad is electrically isolated from all other circuitry in the die. For example, in one possible implementation, the second array bond pad is implemented in the top Aluminum cap layer, but is not connected to any other layers by any underlying via structure or to any other structures within the cap layer other than the corresponding bond wire. In this way, the bond wire will still be charged to the appropriate voltage level and no current will flow through the bond wire.

As such, in either implementation, when interface 108 is operating, each bond wire 112 will have a static voltage equivalent to the appropriate power supply or ground voltage level all along the length of the bond wire with substantially no current flowing through the bond wire. In particular, bond wires 112(1) and 112(3) will be charged to the power supply voltage, and bond wires 112(2) and 112(4) will be charged to the ground voltage.

As represented symbolically in FIG. 1, the juxtaposition of bond wires 112(1) and 112(2) establishes a (parallel-plate) capacitance between those two bond wires, and likewise between bond wires 112(2) and 112(3) and between bond wires 112(3) and 112(4). In particular, the schematic capacitor symbol shown in FIG. 1 represents the capacitance between adjacent wires and is not intended to represent the presence of a discrete capacitor connected between the two wires. Note that there is also capacitance between other pairs of bond wires (e.g., between bond wire 112(1) and 112(4)), but that capacitance will be less due to the greater distance between those bond wires.

With array bond pads 114(1), 114(2), 114(5), and 114(6) all connected to the same power supply voltage and with array bond pads 114(3), 114(4), 114(7), and 114(8) all connected to the same ground voltage, bond wires 112(1)-114(4) will effectively function as a single (charged) capacitor. Some of those array bond pads are also appropriately electrically connected to the internal integrated circuitry of interface 108, such that the charged capacitor functions as a decoupling capacitor for interface 108.

Note that, in FIG. 1, array bond pads 114(1), 114(3), 114(5), and 114(7) are positioned collinearly on die 100 along a first line 116. Similarly, array bond pads 114(2), 114(4), 114(6), and 114(8) are also positioned collinearly on die 100 along a second line 118 that is parallel to the first line 116. This configuration of array bond pads enables bond wires 112(1)-112(4) to be all aligned horizontally at the same altitude above the top surface of die 100, as represented in FIG. 2.

FIG. 2 shows a top view of two horizontally aligned bond wires, such as bond wires 112(1) and 112(2).

Note further that the pattern of alternating sets of power supply and ground bond pads and bond wires can be repeated additional times on die 100 as indicated by broken lines 116 and 118. The number of alternating sets implemented will depend on the desired capacitance of decap 110, with more sets contributing more capacitance.

Additional factors that affect the capacitance of decap 110 are the lengths and thicknesses of bond wires 112(1)-112(4) and the distances between adjacent bond wires. In general, the effective capacitance of decap 110 is directly related to the lengths and thicknesses of the bond wires and indirectly related to the distance between adjacent bond wires. Those skilled in the art will understand that the capacitance of a particular design can be determined analytically and/or experimentally.

In order to optimize (e.g., maximize) the capacitance contributed by a pair of power supply and ground bond wires, such as bond wires 112(1) and 112(2), one or both of the bond wires is insulated such that the bond wires can be in physical contact along much of their lengths without shorting out the capacitor. Using insulated wires for all of the bond wires will also prevent shorting between any two bond wires that may inadvertently come into contact during assembly of the packaged semiconductor device. It will be understood that an insulated bond wire has insulation along its intermediate length and no insulation at its two ends to enable electrical contact with two corresponding bond pads.

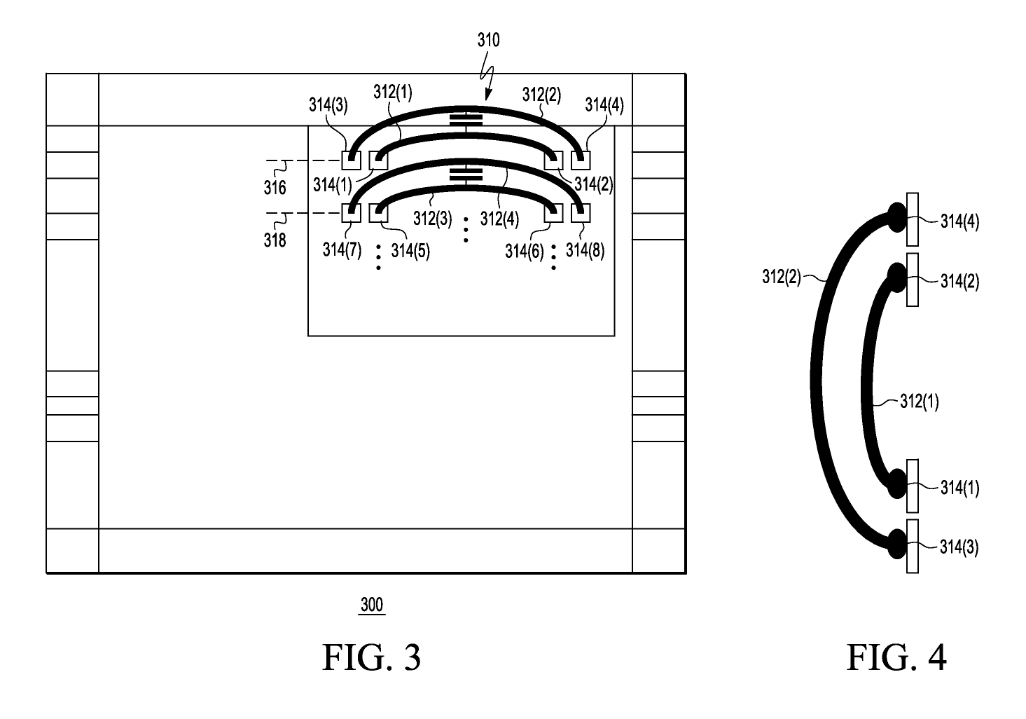

FIG. 3 represents a die 300 of a packaged semiconductor device according to another embodiment of the invention. Die 300 is similar to die 100 of FIG. 1 with corresponding elements labeled using similar labels. Where die 300 differs from die 100 is in the positions of the eight array bond pads 314(1)-314(8) used to form decap 310.

In particular, in FIG. 3, array bond pads 314(1)-314(4) are positioned collinearly on die 300 along a first line 316, while array bond pads 314(5)-314(8) are also positioned collinearly on die 300 along a second line 318 that is parallel to the first line 316. In this case, bond wires 312(1) and 312(2) are stacked vertically, while bond wires 312(3) and 312(4) are also stacked vertically, with bond wires 312(1) and 312(3) aligned horizontally at the same altitude above the top surface of die 100, and bond wires 312(2) and 312(4) aligned horizontally at the same, greater altitude above the top surface of die 100.

FIG. 4 shows a side view of two vertically stacked bond wires, such as bond wires 312(1) and 312(2). Although FIGS. 3 and 4 show an implementation in which the ground bond wire 312(2) is above the power bond wire 312(1), in alternative implementations, the opposite it true.

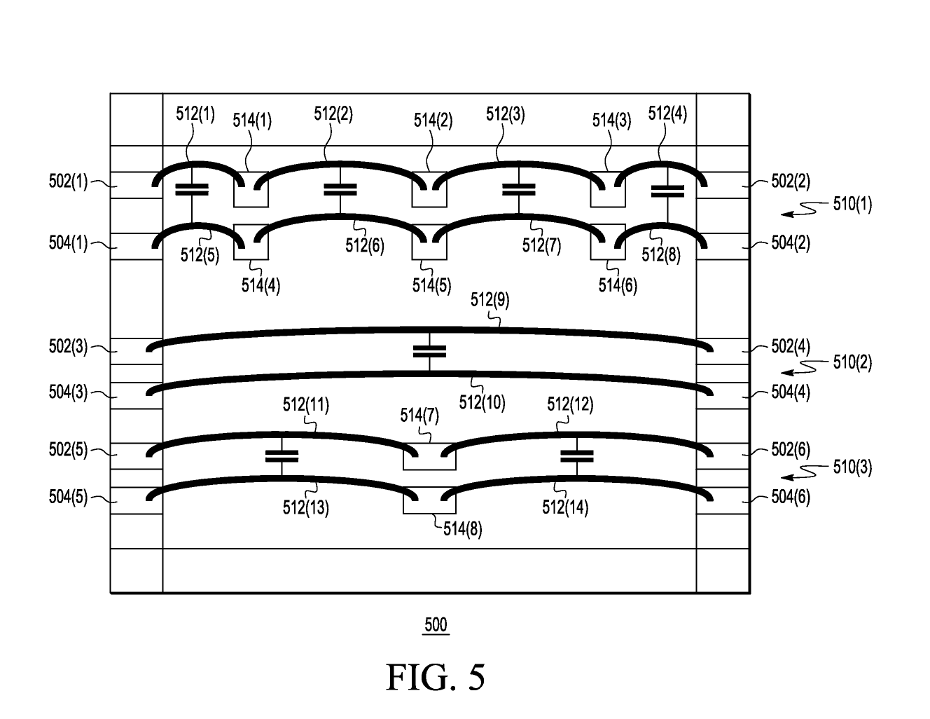

FIG. 5 represents three other ways of implementing decaps according to three other embodiments of the invention. Although FIGS. 1-4 show embodiments in which all of the bond pads used to form the decap are array bond pads, in other embodiments, I/O bond pads can be used instead of or in addition to array bond pads. FIG. 5 shows some of these other embodiments. Note that, although FIG. 5 shows three different decaps on a single die 500, the purpose of FIG. 5 is to illustrate different ways of implementing decaps, not to represent an exemplary die that actually has three decaps, although that may be possible, depending on the die.

In particular, decap 510(1) is implemented using (i) four series-connected power bond wires 512(1)-512(4) interconnected between five collinear power bond pads (i.e., two I/O power bond pads 502(1) and 502(2) and three array power bond pads 514(1)-514(3) and (ii) four series-connected ground bond wires 512(5)-512(8) interconnected between five collinear ground bond pads (i.e., two I/O ground bond pads 504(1) and 504(2) and three array ground bond pads 514(4)-514(6) and parallel to the line defined by the power bond wires 512(1)-512(4).

Decap 510(2) is implemented using (i) a single power bond wire 512(9) interconnected between two I/O power bond pads 502(3) and 502(4) and (ii) a single ground bond wire 512(10) interconnected between two I/O ground bond pads 504(3) and 504(4) and parallel to the line defined by power bond wire 512(9).

Decap 510(3) is implemented using (i) two series-connected power bond wires 512(11) and 512(12) interconnected between three collinear power bond pads (i.e., two I/O power bond pads 502(5) and 502(6) and one array power bond pad 514(7) and (ii) two series-connected ground bond wires 512(13) and 512(14) interconnected between three collinear ground bond pads (i.e., two I/O ground bond pads 504(5) and 504(6) and one array ground bond pad 514(8) and parallel to the line defined by the power bond wires 512(11) and 512(12).

Note that, in still other embodiments, each set of power bond pads includes only one I/O bond pad, and each set of ground bond pads includes only one I/O bond pad.

Although not explicitly represented in FIG. 5, for each (horizontal, in FIG. 5) set of collinear bond pads, one or more of the bond pads in the set are further connected to the appropriate power supply or ground voltage level, while the zero or more remaining bond pads in the set are otherwise electrically isolated. Note that, for an I/O bond pad, the connection may be off-chip via a bond wire (not shown).

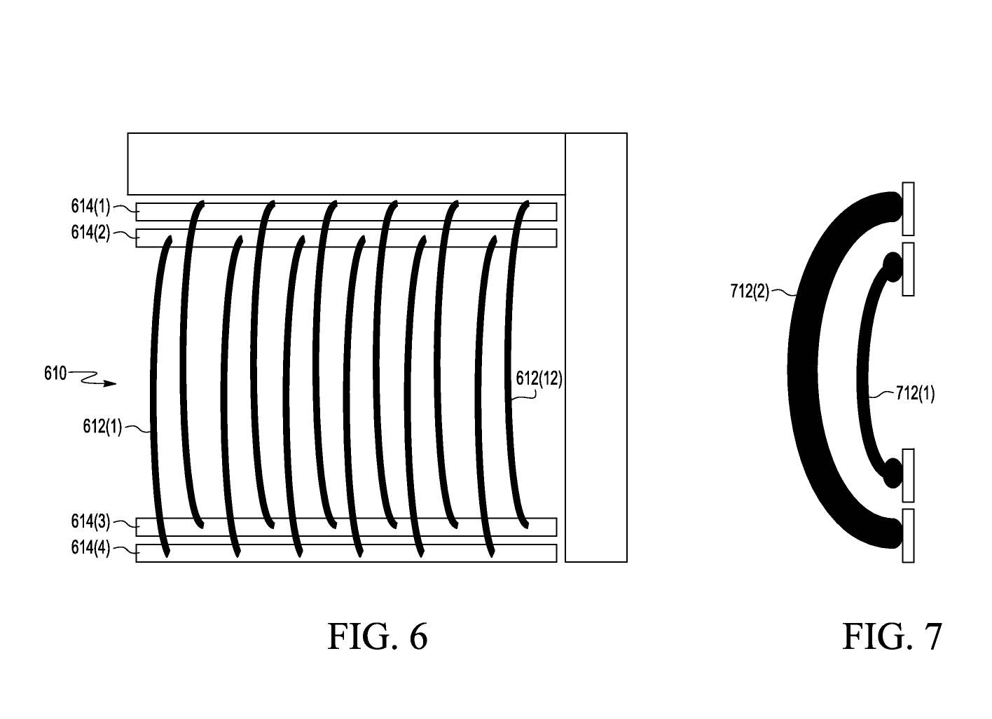

FIG. 6 represents another die decap 610 implemented on a portion of a die corresponding to the location of integrated high-speed logic for a packaged semiconductor device according to another embodiment of the invention. In this embodiment, decap 610 is formed by wire-bonding (i) two elongated power bond pads 614(1) and 614(3) with multiple (e.g., six) power bond wires 612 and (ii) two elongated ground bond pads 614(2) and 614(4) with multiple (e.g., six) ground bond wires 612, where the four elongated bond pads are mutually parallel and the twelve bond wires are substantially horizontally aligned.

Note that, in this embodiment, in the view of FIG. 6, power bond pad 614(1) is above ground bond pad 614(2) and power bond pad 614(3) is above ground bond pad 614(4). In an alternative embodiment, power bond pad 614(1) is above ground bond pad 614(2), while power bond pad 614(3) is below ground bond pad 614(4) (or vice versa), such that each pair of power and ground bond wires 612 may be (but do not have to be) vertically aligned (as in FIGS. 3 and 4), instead of horizontally aligned (as in FIGS. 1 and 2).

Those skilled in the art will understand that the invention also covers packaged semiconductor devices with die decaps having any other suitable configuration of bond pads and bond wires.

Although, as described previously, there may be advantages to using insulated bond wires, the invention can also be implemented using one or more and even all non-insulated bond wires.

In general, the invention covers embodiments in which a decap is formed using two or more bond wires, such that, during operation of the corresponding integrated circuitry (e.g., I/O interface), the bond wires are charged to desired static voltage levels (e.g., power supply or ground) and are not used to carry current between interconnected bond pads, even when one or two of the bond pads are I/O bond pads.

Although not depicted in the figures, after the bond wires are wire-bonded to the bond pads, molding compound or other suitable material is applied over the die and the bond wires to encapsulate them within the packaged device.

FIGS. 1-6 show various embodiments of the invention in which the bond wires have substantially the same diameter (i.e., the same gauge). In alternative embodiments, different wires may have different diameters (gauges). For example, as shown in FIG. 7, the outer bond wire 712(2) may be thicker than the inner bond wire 712(1), or vice versa. The different thicknesses enable substantially the same capacitance to be achieved even when the relative positions of the wires differs slightly from package to package, e.g., due to small displacements that can occur during assembly because of mechanical factors. Although this example involves vertically stacked bond wires, in theory, different wire thicknesses can also be used for horizontally aligned bond wires, such as those in FIGS. 1-2.

By now it should be appreciated that there has been provided an improved packaged semiconductor device and a method of forming the packaged semiconductor device. Circuit details are not disclosed because knowledge thereof is not required for a complete understanding of the invention.

Although the invention has been described using relative terms such as “upper,” “lower,” “front,” “back,” “top,” “bottom,” “over,” “under” and the like in the description and in the claims, such terms are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Unless stated otherwise, terms such as “first” and “second” are used to arbitrarily distinguish between the elements such terms describe. Thus, these terms are not necessarily intended to indicate temporal or other prioritization of such elements. Further, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Although the invention is described herein with reference to specific embodiments, various modifications and changes can be made without departing from the scope of the present invention as set forth in the claims below. Accordingly, the specification and figures are to be regarded in an illustrative rather than a restrictive sense, and all such modifications are intended to be included within the scope of the present invention. Any benefits, advantages, or solutions to problems that are described herein with regard to specific embodiments are not intended to be construed as a critical, required, or essential feature or element of any or all the claims.

1. A packaged semiconductor device, comprising:
a semiconductor die having a plurality of bond pads;
a first bond wire wire-bonded between a first bond pad and a second bond pad, wherein the first and second bond pads are configured to be charged to a first voltage level; and
a second bond wire wire-bonded between a third bond pad and a fourth bond pad, wherein the second bond wire is adjacent to the first bond wire, and the third and fourth bond pads are configured to be charged to a second voltage level different from the first voltage level such that the first and second bond wires function as a decoupling capacitor for the die.

2. The device of claim 1, wherein the first and second bond wires are insulated bond wires having insulation along their respective intermediate lengths.

3. The device of claim 1, wherein the decoupling capacitor provides charge for integrated circuitry implemented within the die in a location below the decoupling capacitor.

4. The device of claim 1, wherein, when charged to the first and second voltage levels, respectively, no current flows through the first and second bond wires.

5. The device of claim 1, wherein the first bond wire is substantially parallel to the second bond wire.

6. The device of claim 1, wherein:
the first and second bond pads lie along a first line;
the third and fourth bond pads lie along a second line parallel to the first line; and
the first bond wire is horizontally aligned with the second bond wire.

7. The device of claim 1, wherein:
the first, second, third, and fourth bond pads are substantially collinear; and
the first bond wire is vertically aligned with the second bond wire.

8. The device of claim 1, wherein the first bond pad is an array pad.

9. The device of claim 8, wherein the first bond pad is electrically connected to internal die circuitry that provides the first voltage level to the first bond pad.

10. The device of claim 8, wherein the first bond pad is electrically isolated from all internal die circuitry such that the first voltage level is provided to the first bond pad by the first bond wire.

11. The device of claim 8, wherein the second bond pad is an array pad.

12. The device of claim 8, wherein the second bond pad is an input/output (I/O) pad.

13. The device of claim 1, wherein the first bond pad is an I/O pad.

14. The device of claim 13, wherein the first bond pad is connected by another bond wire to an external power supply having the first voltage level.

15. The device of claim 13, wherein the first bond pad is electrically connected to internal die circuitry that provides the first voltage level to the first bond pad.

16. The device of claim 13, wherein the second bond pad is an I/O pad.

17. The device of claim 1, further comprising:
a third bond wire wire-bonded between fifth and sixth bond pads configured to be charged to the first voltage level; and
a fourth bond wire wire-bonded between seventh and eighth bond pads configured to be charged to the second voltage level, wherein the third and fourth bond wires are substantially parallel to the first and second bond wires and function as an additional part of the decoupling capacitor for the die.

18. The device of claim 1, further comprising:
a third bond wire wire-bonded between the second bond pad and a fifth bond pad, wherein the fifth bond pad is configured to be charged to the first voltage level; and
a fourth bond wire wire-bonded between the fourth bond pad and a sixth bond pad and adjacent to the third bond wire, wherein the sixth bond pad is configured to be charged to the second voltage level, such that the third and fourth bond wires function as an additional part of the decoupling capacitor for the die.

19. The device of claim 1, further comprising:
a third bond wire wire-bonded between the first and second bond pads; and
a fourth bond wire wire-bonded between the third and fourth bond pads, such that the third and fourth bond wires function as an additional part of the decoupling capacitor for the die.

20. The device of claim 1, wherein the first and second bond wires have different diameters.
